(19) United States
(12) Patent Application Publication
(10) Pub. No.: US 2009/0195336 A1
(43) Pub. Date: Aug. 6, 2009

(54) TUNABLE VOLTAGE-CONTROLLED OSCILLATOR

(76) Inventor: Cho-Chun HUANG, HsinChu city (TW)

Correspondence Address: SINORICA, LLC, 2275 Research Blvd., Suite 500, ROCKVILLE, MD, 20850, US

(21) Appl. No.: 12/198,171

(22) Filed: Aug. 26, 2008

(30) Foreign Application Priority Data
Feb. 5, 2008 (TW) 097104426

(51) Int. Cl. H03J 5/12; H03B 5/12

(52) U.S. Cl. 334/15; 331/49

(57) ABSTRACT

A multi-band VOC includes a plurality of oscillators, each oscillators having an oscillatory range respectively; a plurality of capacitor tanks is provided in each oscillators, and each capacitors is composed of a plurality of capacitors in series connection; a voltage detecting device is provided to detect a voltage signal, and to select an oscillator; one end of a logic controller is provided to electrically connect to the voltage detecting device, and another end is provided to electrically connect to the capacitor tank, which is provided a control signal to drive capacitance of the capacitor tank; and a multiple device is provided to output an oscillation frequency.

### BACKGROUND OF THE INVENTION

1. Field of the Invention

The present invention is related to a tuner, and more particularly, is a tunable multi-bands voltage-controlled oscillator (VCO) and a tuner formed thereof.

2. Description of the Prior Art

Because the improvement of the communicative and the depressive technique, the global television broadcast system is switched from analog to digital. The change of the digital TV broadcast will trigger the high development of the relative industry, such as Set-Top-Box (STB) or high definition television (HDTV). In future, the digital TV broadcast will go mobile and the TV shows will be available at anytime and anywhere. Therefore, the tuner circuit in the STB and HDTV is a key issue in the industry.

FIG. 1A is a view of a conventional tuner included single conversion with intermediate frequency (IF). As shown in FIG. 1A, the tuner 100 includes a filter 101, a low noise amplifier 102 (LNA), a mixer 106, a local oscillator 110 and a filter 112. The filter 101 and the filter 112 are SAW filter. The radio frequency (RF) (such as frequency within 50˜860 MHz) received by the antenna (not shown) of the tuner 100 is transmitted from the filter 101 to the LNA 102 to be amplified. Then, the mixer 106 and the local oscillator 110 are used to decrease the amplified radio frequency to be the frequency within the intermediate frequency range, such as 36 MHz. The filter 112 is used to select the suitable channel.

FIG. 1B is a view of a conventional tuner included dual conversion with IF. As shown in FIG. 1B, the tuner 100 includes a low noise amplifier 102 (LNA), an IF/RF mixer 106a, a band-pass filter 104, an IF/IF mixer 106b, and a filter 112. One end of the low noise amplifier 102 is connected the antenna and the low noise amplifier 102 amplifiers the radio frequency. Then, the mixer 106a and the local oscillator 110A are used to increase the amplified radio frequency to be the frequency within the intermediate frequency range, such as 1 GHz. One end of the mixer 106a is connected to the output end of the low noise amplifier. The local oscillator 110A is connected to another end of the mixer 106a and used to provide a frequency of the local oscillator, such as 1 GHz˜2 GHz. Then, the input end of the band-pass filer 104 is connected to the output end of the mixer 106a and used to filer the noise and output the intermediate frequency from another end. The mixer 106b and the local oscillator 110B are used to decrease the first intermediate frequency to be the second intermediate frequency. The filter 112 is used to select the suitable channel. Moreover, the filter 112 can be a channel select filter used to select a desired channel and filter other unwanted channels. Obviously, the tuner with the dual conversion with IF is able to filter the mirror signals without using a lot of filters.

FIG. 1C is a view of a conventional tuner including dual conversion with low IF. As shown in FIG. 1C, the radio frequency is transmitted into the low noise amplifier 102 to be amplified and divided into I Path and Q Path by a RF poly-phase filter. Then the frequency is transmitted into the complex mixer (also called dual quadrature mixer). The complex mixer 114 is made by a plurality of mixers 106. The quadrature local oscillator 111 will transmit the oscillated frequency to the complex mixer 114 to be mixed into I Path and Q Path quadrature low IF. The quadrature local oscillator 111 is generated by the local oscillator 111 and a divider 110 (such as divided by 2). Another IF poly-phase filter 113 will transform the I Path and Q Path low IF quadrature signal to be the I Path and Q Path low IF signal to decrease the frequency and filter the mirror frequency. At final, the channel select filter is used to select the desired channel and filter other unwanted channels. Therefore, the function of the tuner is completed.

FIG. 1D is a view of a conventional tuner including dual conversion with low IF. As shown in FIG. 1D, the radio frequency is transmitted into the low noise amplifier 102 to be amplified, and increased the frequency to be IF and mixed into in-phase frequency 1 (IIF1) and quadrature phase by a first quadrature mixer 120 and a first quadrature LO 117. Then the frequency is mixed into quadrature low IF of the IIF1 and the QIF1 by the complex mixer 122 and the second quadrature LO 119. The IF poly-phase filter 118 is used to transform the quadrature low IF signals of the IIF1 and the QIF1 into low IF signals to decrease the frequency and filter the mirror frequency. The channel select filter 116 is used to select the desired channel and filter other unwanted channels. Therefore, the function of the tuner is completed.

Besides, in a tuner, the voltage-controlled oscillator is an important device, because it is a local oscillator used to form the up conversion or down conversion device. Because the basic oscillated theory of the oscillator is using inductance and capacitance to form an oscillated frequency, the basic formula is f=½π(LC)½.

In addition, in order to integrate the tuner, the regular voltage-controlled oscillator (VCO) uses a constant inductance and the adjustable capacitance is used to adjust the oscillated frequency. In prior art, the phase lock loop is used to phase symphonize the input signal and the oscillated frequency, as shown in FIG. 2A.

However, in a VCO, in order to generate a desired oscillated frequency, the capacitor tank is used. In U.S. Pat. No. 6,803,830, it is a device can automatically adjust the output signal of the VCO, as shown in FIG. 2B. The output signal of the VCO is used to be the feedback signal to adjust the signal in the desired frequency range. In addition, in U.S. Pat. No. 6,836,193, it is a method using a similar capacitor tank to adjust the oscillated frequency of the VCO, as shown in FIG. 2C. However, the capacitor tank includes a complex structure, the semiconductor manufacture complication is increased and those complicated capacitor occupy too many area of the integrated circuit.

Obviously, only a short band is able to be adjusted in prior art. But the multi-bands adjustable function can not be achieved.

### SUMMARY OF THE INVENTION

According to the problems described above, a multi-band VCO is disclosed in the present invention.

The main object of the present invention is to provide a function with multi-band tuning.

Another object of the present invention is to provide a multi-band VCO and the multi-band VCO can choose one of the multi-bands to let the oscillator can adjust in the best setting.

Besides, one object of the present invention is to provide a tuner structure with multi-bands VCO. The tuner can have a better phase noise.

Another object of the present invention is to provide a low noise amplifier structure to broadband noise optimum to enhance gain and the gain flatness.

One object of the present invention is to provide a tuner structure and the tuner can be operated at optimum power consumption to decrease the power lost in the tuner.

Other object of the present invention is to provide a tuner structure to be operated at optimum power consumption and optimum performance condition.

According to the objects described above, a tunable multi-bands voltage-controlled oscillator (VCO) is disclosed herein and comprises a plurality of oscillators, a plurality of capacitor tanks, a voltage detector, a logic controller and a multiplexer. Each of the oscillators includes different oscillated range. The capacitor tanks are respectively disposed in each one of the oscillators and each one of the capacitors includes a plurality of parallel connective capacitors. The voltage detector is used to detect a voltage signal and choose one of the oscillators in accordance with the voltage signal. One end of the logic controller is connected to the voltage detector and the other end of the logic controller is connected to the capacitor tanks and provides a controlled signal to drive the capacitors of the capacitor tanks. One end of the multiplexer is connected to the logic controller and the oscillators to output an oscillated frequency.

The present invention also discloses a frequency synthesizer including a phase/frequency detector, a power pump, a loop filter and a multi-bands VCO, and the multi-bands VCO is characterized in that comprising a plurality of oscillators, a plurality of capacitor tanks, a voltage detector, a logic controller and a multiplexer. Each of the oscillators includes different oscillated range. The capacitor tanks are respectively disposed in each one of the oscillators and each one of the capacitors includes a plurality of parallel connective capacitors. The voltage detector is used to detect a voltage signal and choose one of the oscillators in accordance with the voltage signal. One end of the logic controller is connected to the voltage detector and the other end of the logic controller is connected to the capacitor tanks and provides a controlled signal to drive the capacitors of the capacitor tanks. One end of the multiplexer is connected to the logic controller and the oscillators to output an oscillated frequency.

The present invention also discloses a frequency synthesizer including a multi-bands VCO and a mixer, and the multi-bands VCO is characterized in that comprises a plurality of oscillators, a plurality of capacitor tanks, a voltage detector, a logic controller and a multiplexer. Each of the oscillators includes different oscillated range. The capacitor tanks are respectively disposed in each one of the oscillators and each one of the capacitors includes a plurality of parallel connective capacitors. The voltage detector is used to detect a voltage signal and choose one of the oscillators in accordance with the voltage signal. One end of the logic controller is connected to the voltage detector and the other end of the logic controller is connected to the capacitor tanks and provides a controlled signal to drive the capacitors of the capacitor tanks. One end of the multiplexer is connected to the logic controller and the oscillators to output an oscillated frequency.

The present invention also discloses a broadband tuner including a filter, a low noise amplifier, a mixer and a multi-bands VCO, and the multi-bands VCO is characterized in that comprises a plurality of oscillators, a plurality of capacitor tanks, a voltage detector, a logic controller and a multiplexer. Each of the oscillators includes different oscillated range. The capacitor tanks are respectively disposed in each one of the oscillators and each one of the capacitors includes a plurality of parallel connective capacitors. The voltage detector is used to detect a voltage signal and choose one of the oscillators in accordance with the voltage signal. One end of the logic controller is connected to the voltage detector and the other end of the logic controller is connected to the capacitor tanks and provides a controlled signal to drive the capacitors of the capacitor tanks. One end of the multiplexer is connected to the logic controller and the oscillators to output an oscillated frequency.

The present invention also discloses a broadband tuner made by serial connective of a first single frequency conversion device and a second single frequency conversion device, wherein the first single frequency conversion device includes a filter, a low noise amplifier, a mixer and a multi-bands VCO, and the second single frequency conversion device includes a filter, a low noise amplifier, a mixer and a multi-bands VCO, are characterized in that and comprise a plurality of oscillators, a plurality of capacitor tanks, a voltage detector, a logic controller and a multiplexer. Each of the oscillators includes different oscillated range. The capacitor tanks are respectively disposed in each one of the oscillators and each one of the capacitors includes a plurality of parallel connective capacitors. The voltage detector is used to detect a voltage signal and choose one of the oscillators in accordance with the voltage signal. One end of the logic controller is connected to the voltage detector and the other end of the logic controller is connected to the capacitor tanks and provides a controlled signal to drive the capacitors of the capacitor tanks. One end of the multiplexer is connected to the logic controller and the oscillators to output an oscillated frequency.

The present invention also discloses an adjusting output frequency of a multi-bands VCO a plurality of oscillators, a plurality of capacitor tanks, a voltage detector, a logic controller and a multiplexer. Each of the oscillators includes different oscillated range. The capacitor tanks are respectively disposed in each one of the oscillators and each one of the capacitors includes a plurality of parallel connective capacitors. The voltage detector is used to detect a voltage signal and choose one of the oscillators in accordance with the voltage signal. One end of the logic controller is connected to the voltage detector and the other end of the logic controller is connected to the capacitor tanks and provides a controlled signal to drive the capacitors of the capacitor tanks. One end of the multiplexer is connected to the logic controller and the oscillators to output an oscillated frequency.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a view of a conventional tuner included single conversion with IF;

FIG. 1B is a view of a conventional tuner included dual conversion with IF;

FIG. 1C is a view of a conventional tuner included dual conversion with low IF;

FIG. 1D is a view of a conventional tuner including dual conversion with low IF;

FIGS. 2A-2C are views showing a conventional voltage-controlled oscillator (VCO) in prior art;

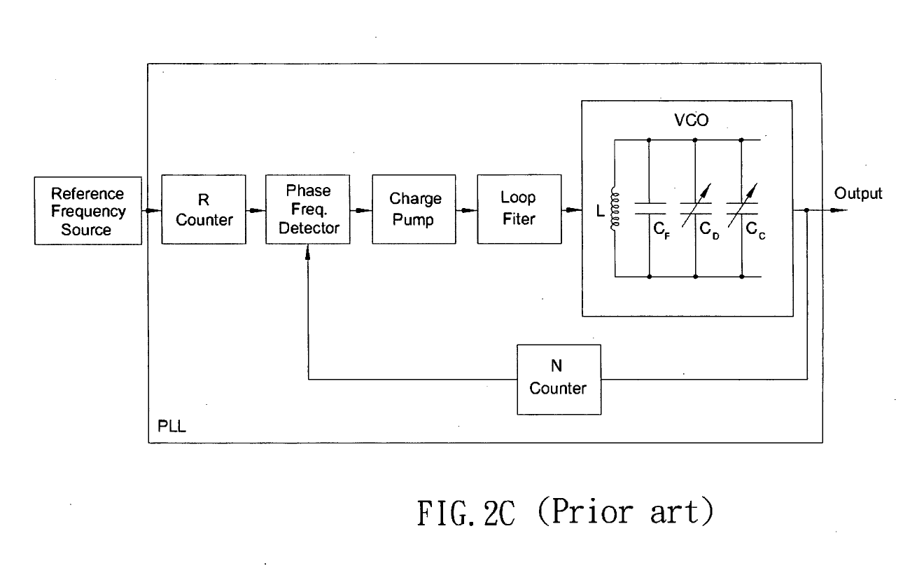

FIG. 3 is a view showing that a main structure of a multi-bands VCO in the present invention;

FIG. 4 is a view showing the multi-bands VCO of the present invention including phase lock loop circuit;

FIG. 5 is a view showing the multi-bands VCO of the present invention;

FIG. 6 is view showing another embodiment of the multi-bands VCO in the present invention;

FIG. 7 is a view showing the dual conversion tuner of the present invention including the multi-bands VCO;

FIGS. 8A-8B are views showing the low noise amplifier of the present invention;

FIGS. 9A-9B are views showing another embodiment of the low noise amplifier of the present invention; and

FIG. 10 is one another embodiment of the low noise amplifier of the present invention.

### DESCRIPTION OF THE PREFERRED EMBODIMENT

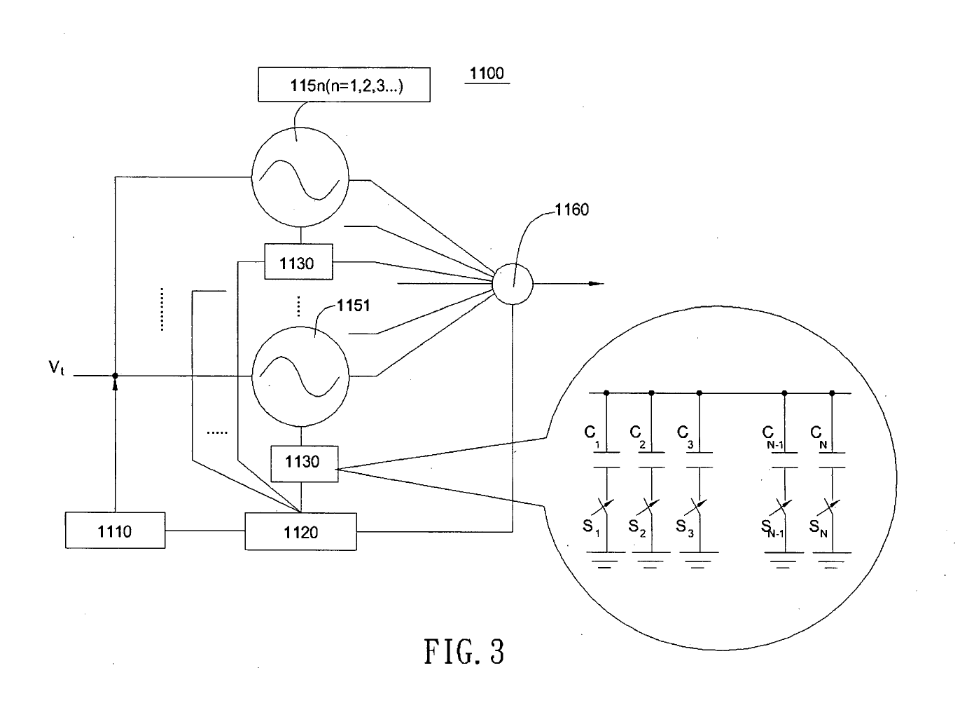

FIG. 3 is view showing that a main structure of a multi-bands voltage-controlled oscillator (VCO) in the present invention. As shown in FIG. 3, the multi-bands VCO 1100 includes a voltage detector 1110, a logic controller 1120, a multiplexer 1160, a plurality of oscillator 115n (n =1, 2, 3 . . . ) with different oscillated ranges, and a plurality of capacitor tanks 1130. Each one of the capacitor tanks is connected to a oscillator 115n (n=1, 2, 3 . . . ). Each one of the capacitor tanks includes a plurality of capacitors C_{N} (N=1, 2, 3 . . . ). Each one of the capacitors in the capacitor tank includes a switch SN (N=1, 2, 3 . . . ) used to control the capacitor value of the capacitor tank in accordance with the digital signals provided by the logic controller 1120.

Besides, because the oscillator 115n (n=1, 2, 3 . . . ) includes at least one active component, an inductance and a capacitor. The inductance and the capacitor are parallel to form the oscillated source of the oscillator 115n (n=1, 2, 3 . . . ). Therefore, when the capacitors C_{N} (n=1, 2, 3 . . . ) of the capacitor tank 1130 is parallel and connected to the capacitor of the oscillators 115n (n=1, 2, 3 . . . ), the capacitor value of the oscillators 115n (n=1, 2, 3 . . . ) can be changed by controlling the switch SN (N=1, 2, 3 . . . ) of the capacitor tanks 1130. The oscillator 115n is adjusted in optimum condition and the output is transmitted by the multiplexer 1160.

Still referring to FIG. 3, when the multi-bands VCO 1100 is driven by a tuning voltage (Vₜ) input, one of the oscillator 115n (n=1, 2, 3 . . . ) will be chosen in accordance with the voltage (Vₜ) detected by the voltage detector 1110 and the logic controller 1120 and the multiplexer 1160. For example, multi-bands VCO 1100 includes the oscillator 115n (n=1, 2, 3 . . . ) with four different ranges. When the voltage (Vₜ) detected by the voltage detector 1110 is within the oscillated range of the multi-bands VCO 1100, such as Vₜ=1V, the voltage detector 1110 will transmit the voltage Vₜ to the logic controller 1120 and the logic controller 1120 can output control signals to the multiplexer 1160 and the multiplexer can choose the oscillator 1151.

If the voltage Vₜ detected by the voltage detector 1110 is not within the oscillated range, such as Vₜ=5V, the voltage detector 1110 will transmit the voltage Vₜ to the logic controller 1120. And the logic controller 1120 will control the number of the capacitors in the capacitor tanks 1130 of the oscillators 115n (n=1, 2, 3 . . . ). For example, during the period of the adjusting of the number of the capacitors, the logic controller 1120 will output a digital control signal with ramp up or ramp down to the counter (not shown) of the logic controller 1120 by increasing or decreasing the capacitor value to adjust the oscillated range of the oscillator 1151. Therefore, the oscillator 1151 will be adjusted in the optimum condition.

When the multi-bands VCO 1100 is adjusted in the optimum phase noise condition, the logic controller 1120 will transmit a control signal to drive the multiplexer 1160 to choose one of the best oscillator 115n (n=1, 2, 3 . . . ). Finally, the output is transmitted by the mixer 106. It should be noted that the number of the oscillator 115n (n=1, 2, 3 . . . ) of the present invention is more than one, the number of the oscillator 115n (n=1, 2, 3 . . . ) can be increased or decreased by the requirement. It is not limited herein.

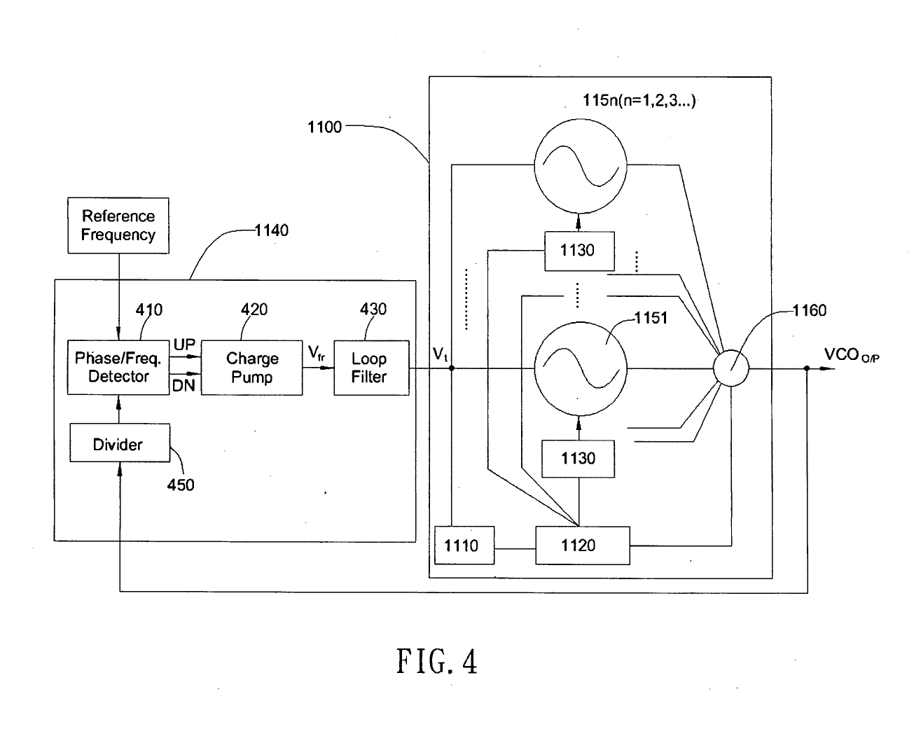

In other preferred embodiment of the present invention, a frequency synthesizer 1500 formed by a multi-bands VCO 1100 and a phase lock feedback (PLL) 1140. As shown in FIG. 4, the PPL 1140 includes a phase/frequency detector (PFD) 410, a charge pump 420 (CP) and loop filter 430 (LF). The multi-bands VCO 1100 includes a voltage detector 1110, a logic controller 1120, a multiplexer 1160, a plurality of oscillator 115n (n=1, 2, 3 . . . ) with different oscillated ranges and a plurality of capacitor tanks 1130.

Each one of the capacitor tanks is connected to an oscillator 115n (n=1, 2, 3 . . . ). Each one of the capacitor tanks includes a plurality of capacitors C_{N} (N=1, 2, 3 . . . ). Each one of the capacitors in the capacitor tank includes a switch S_{N} (N=1, 2, 3 . . . ) used to control the capacitor value of the capacitor tank in accordance with the digital signals provided by the logic controller 1120.

Still referring to FIG. 4, the PFD 410 in the phase lock loop 1140 detects the different between the reference frequency input and the inner oscillated signal and converts the compare result into at least one digital signal outputs, such as V_{UP} and V_{DN}. After the CP 420 received the V_{UP} and V_{DN} signals transmitted from the PFD 410, the V_{UP} and V_{DN} signals are transformed to be a controlled voltage V_{fr} and outputted to the loop filter 430. The loop filter 430 can filter the high frequency of the controlled voltage.

Then, the voltage detector 1110 of the multi-bands VCO 1100 will output a voltage signal Vₜ used to choose a best oscillator in accordance with the loop filter 430. For example, when the voltage Vₜ outputted by the loop filter 430 is 1V (near first wave, such as 2˜2.5 GHz), the voltage detector 1110 chooses the oscillator 1151. The voltage detector 1110 will transmit the voltage Vₜ to the logic controller 1120. The logic controller 1120 will output controlled signal to the multiplexer 1160. The multiplexer 1160 will choose the best oscillator. When the voltage detected by the voltage detector 1110 is not within the oscillated range of the multi-bands VCO 1100, such as Vₜ=5V, the voltage detector 1110 will output the voltage Vₜ to the logic controller 1120. The logic controller 1120 will control the number of the capacitors in the capacitor tanks 1130 connected to the oscillator 115n (n=1, 2, 3 . . . ). For example, in the present embodiment, the capacitor tanks can be divided into 16 sub-bands. Each of the capacitor is within 30˜32 MHz frequency range. Besides, the capacitor tanks 1130 can increase or decrease the capacitor value to adjust the oscillated frequency of the oscillator 1151. The oscillator 1151 can be adjusted in optimum condition. Especially, the frequency device 1150 is adjusted in optimum phase noise, and the output is transmitted from the multiplexer 1160 to the mixer 106.

It should be noted that the phase lock loop 1140 is an electronic component well known in the art. Therefore, the detail circuit structure and the operated procedure are not described herein. When the phase lock loop 1140 and the multi-bands VCO 1100 of the present invention are operated together, the stability of the multi-bands VCO 1100 is increased, the bandwidth is increased and the oscillated frequency locked time is decreased. Besides, the phase lock loop 1140 is able to connect a frequency divider 450 and the frequency divider 450 is disposed between the output end of the multi-bands VCO 1100 and the input end of the phase/frequency detector 410. The frequency divider 450 is used to decrease the output frequency of the multi-bands VCO 1100 and the frequency decreased by the frequency divider 450 is able to compare with the input reference frequency.

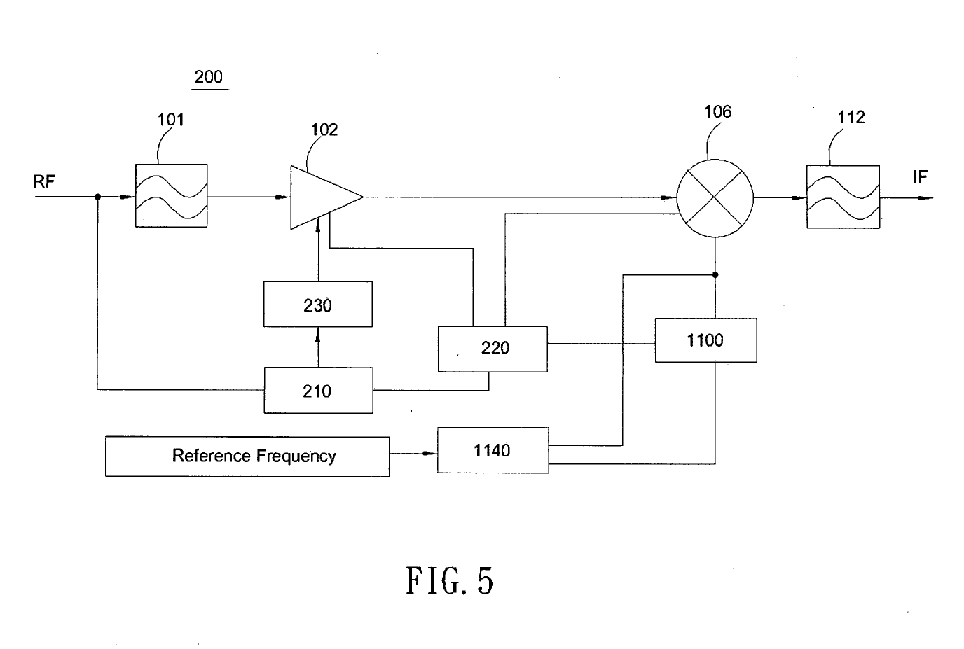

FIG. 5 is a view showing that the main structure of a tuner 200 with single conversion with IF. The tuner 200 is a heterodyne tuner or a broadband tuner, such as digital TV tuner. As shown in FIG. 5, the tuner 200 includes a filter 101, a low noise amplifier (LNA) 102, a mixer 106, a filter 112, a phase lock loop 1140 and a multi-bands VCO 1100. The multi-bands VCO 1100 includes a voltage detector 1110, a logic controller 1120, a multiplexer 1160, a plurality of oscillator 115n (n=1, 2, 3 . . . ) with different oscillated ranges, and a plurality of capacitor tanks 1130. Each one of the capacitor tanks is connected to an oscillator 115n (n=1, 2, 3 . . . ). Each one of the capacitor tanks includes a plurality of capacitors C_{N} (N=1, 2, 3 . . . ). Each one of the capacitors in the capacitor tank includes a switch S_{N} (N=1, 2, 3 . . . ) used to control the capacitor value of the capacitor tank in accordance with the digital signals provided by the logic controller 1120. Besides, the tuner 200 of the present invention further includes a power manage module. The power manage module includes a power detector 210 and a power manage device 220. In addition, the filter 101 and the filter 112 can be a SAW filter.

When the antenna (not shown) of the tuner 200 receives the radio frequency (such as frequency 2˜4 GHz) and transmits the radio frequency to the low noise amplifier 102. The low noise amplifier 102 will amplifier the frequency and the frequency will be transmitted to the mixer 106. The mixer 106 will mix the radio frequency and the oscillated frequency of the multi-bands VCO 1100 and output a oscillated frequency, such as mixing with a natural frequency or a central frequency. The phase lock loop 1140 will detect the different between the input radio frequency and the inner oscillated frequency and output a voltage with phase synchronizing to the oscillated frequency. The voltage detector 1110 of the multi-bands VCO 1100 will output a voltage in accordance with the loop filter 430 to choose a best oscillator. For example, when the loop filter 430 transmits a voltage in the first wave, such as 2˜2.5 GHz, the voltage detector 1110 can choose the oscillator 1151. The voltage detector 1110 will transmit the voltage to the logic controller 1120. The logic controller 1120 will output a digital controlled signal to control the number of the capacitors C_{N}. In the present embodiment, the capacitor tanks can be divided into 16 sub-bands. Each of the capacitor is within 30˜32 MHz frequency range. Besides, the capacitor tanks 1130 can increase or decrease the capacitor value to adjust the oscillated frequency of the oscillator 1151. The oscillator 1151 can be adjusted in optimum condition. Especially, the frequency device 1150 is adjusted in optimum phase noise, and the output is transmitted from the multiplexer 1160 to the mixer 106.

In one preferred embodiment of the present invention, the power detector 210 also detects the power level of the radio frequency of the first wave. The power level value will be transmitted to the power manage device 220. For example, the power manage device 220 is a power/current mode controller. In other words, the power detector 210 will transmit the power level to the low noise amplifier 102 to adjust the power operation of the noise amplifier.

When the power mange device 220 receives the power level, the power manage device 220 will determine the value of the power level. When the input power lever is a large signal, such as more than 50 dbm, the power manage device 220 will set the tuner in a max current mode controlling condition and output a current control signal to the low noise amplifier, such as output a current control signal with minimum gain. Besides, in the preferred embodiment of the present invention, there is an automatic gain control circuit 230 disposed between the power detector 210 and the low noise amplifier 102. The power detector 210 will transmit the power level to the automatic gain control circuit 230 and the automatic gain control circuit 230 will transmit the signal to the low noise amplifier 102. Therefore, the low noise amplifier 102 can be operated at the better power level. Besides, the power manage device 220 is able to be directly connected to the lower noise amplifier 102, the mixer 106, the multi-bands VCO 1100 and any other circuit device (not shown), as shown in FIG. 5. Therefore, when the power manage device 220 receives the power lever detected by the power detector 210, the power manage device 220 will adjust the current of the lower noise amplifier and/or the mixer 106 in accordance with the power lever and adjust the current operating condition of other circuit devices to form the optimum condition of those circuits with the low noise amplifier 102. Besides, at the same period, the power manage device 220 will control the current of the low noise amplifier 102 in accordance with the frequency of the oscillator to avoid the signal gain is large enough to overflow to the mixer 106 or local oscillator and the frequency shift problem is occurred. Obviously, according to the power detector 210 and the power manage device 220 in the power manage module, the tuner 200 of the present invention can operate in the optimum power consumption and the optimum condition when the input power is a large signal.

When the input power lever is a small signal, such as less than 10 dbm, the power manage device 220 will set the tuner in a min current mode controlling condition and output a current control signal to the low noise amplifier 102, such as output a current control signal with maximum gain. In the preferred embodiment of the present invention, there is an automatic gain control circuit 230 disposed between the power detector 210 and the low noise amplifier 102. The power detector 210 will transmit the power level to the automatic gain control circuit 230 and the automatic gain control circuit 230 will transmit the signal to the low noise amplifier 102. Therefore, the low noise amplifier 102 can be operated at the better power level. Besides, the power manage device 220 is able to be directly connected to the lower noise amplifier 102, the mixer 106, the multi-bands VCO 1100 and any other circuit device (not shown), as shown in FIG. 5. Therefore, when the power manage device 220 receives the power lever detected by the power detector 210, the power manage device 220 will adjust the current of the lower noise amplifier and/or the mixer 106 in accordance with the power lever and adjust the current operating condition of other circuit devices to form the optimum condition of those circuits with the low noise amplifier 102. Obviously, according to the power detector 210 and the power manage device 220 in the power manage module, the tuner 200 of the present invention can operate in the optimum power consumption and the optimum condition when the input power is a large signal.

When the input power level is between 10 dbm and 50 dbm, such as 30 dbm, the power detector 210 won't change the gain of the low noise amplifier 102. The regular standard of the low noise amplifier is operated, such as the gain is changed in a linear range. Similarly, the power manage device 220 will adjust the current of the low noise amplifier 102 and/or the mixer 106 in accordance with the current power lever and also adjust the operative condition of the other circuit devices. These circuit devices and the low noise amplifier 102 are in optimum condition. Therefore, the tuner 200 is able to operate at the optimum power consumption and the optimum condition.

As the description above, when the low noise amplifier 102 will amplifier the radio signal of the first wave with the suitable power lever in accordance with the controlled signal of the automatic controlled circuit 230. At final, the filer 112 will filer unnecessary channels to complete the tune function of the tuner.

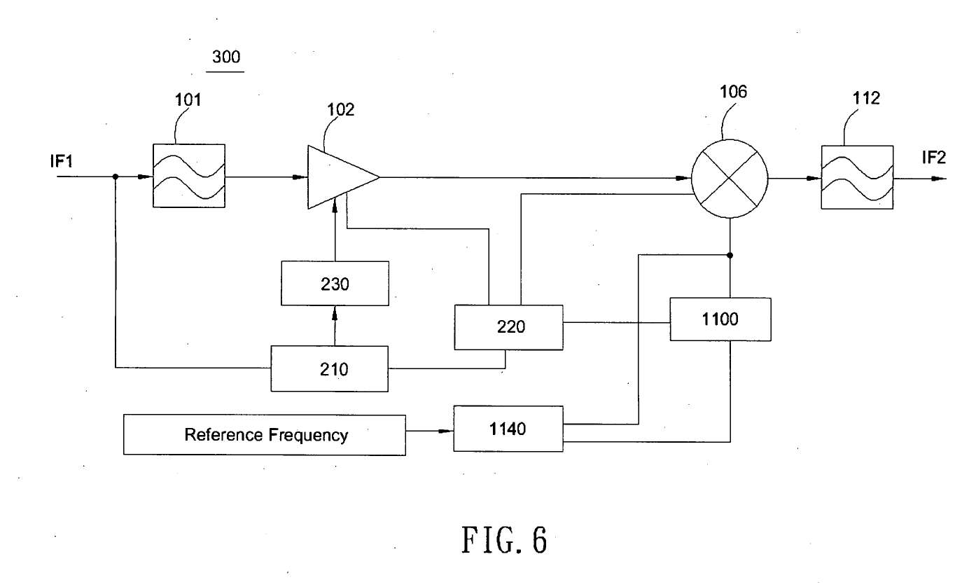

Besides, it should be noted that the multi-bands VCO 1100, the power manage module, the low noise amplifier 102 and the mixer 106 are able to be composed together and formed a frequency conversion apparatus 300. The multi-bands VCO 1100 and the mixer 106 are formed together to be a frequency synthesizer used to up-conversion or down-conversion. The input signal is limited to be a radio frequency (such as input is an intermediate frequency), as shown in FIG. 6.

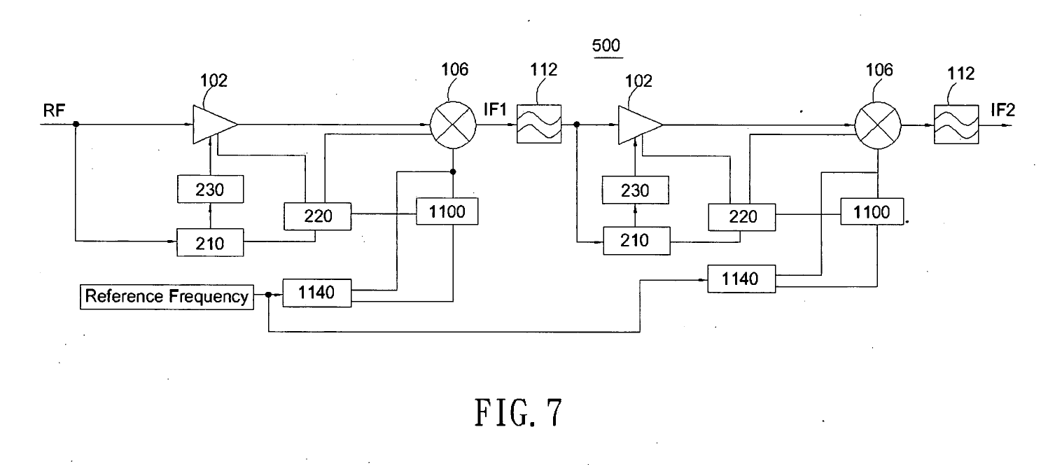

FIG. 7 is a view showing a dual conversion with IF tuner 500. As shown in FIG. 7, the tuner 500 includes two signal conversion units serially connected to each other. The pre-conversion unit and the post-conversion unit respectively include a radio/intermediate frequency mixer 106a, a filter 112, a multi-bands VCO 1100, a phase lock loop 1140 and a power manage module. The multi-bands VCO 1100 includes a voltage detector 1110, a logic controller 1120, a multiplexer 1160, a plurality of oscillator 115n (n=1, 2, 3 . . . ) with different oscillated ranges, and a plurality of capacitor tanks 1130. Each one of the capacitor tanks is connected to a oscillator 115n (n=1, 2, 3 . . . ). Each one of the capacitor tanks includes a plurality of capacitors C_{N} (N=1, 2, 3 . . . ). Each one of the capacitors in the capacitor tank includes a switch S_{N} (N=1, 2, 3 . . . ) used to control the capacitor value of the capacitor tank in accordance with the digital signals provided by the logic controller 1120. The power manage module includes a power detector 210 and a power manage device 22. Optionally, there is an automatic gain controller 230 disposed between the power detector 210 and the power manage device 220. Besides, the pre-conversion unit can be formed a up-conversion unit in accordance with the multi-bands VCO 1100, for example the oscillated frequency of the multi-bands VCO is 1 GHz-2 GHz. The pose-conversion unit can be formed a down-conversion unit by setting a specific oscillated frequency of the local oscillator 110b.

Because the tuner 500 with dual conversion with IF includes two single conversion units serially connected to each other. The pre-conversion unit includes a low noise amplifier 102, a radio/intermediate frequency mixer 106a, a multi-bands VCO 1100, a phase lock loop 1140 and a power manage module. Because the operative procedure of the signal conversion unit is the same as the embodiments described in FIG. 5 and FIG. 6, the detail description of the single conversion unit is omitted. It should be noted that the two signal conversion units are operated by the multi-bands VCO 1100, the phase lock loop 1140 and the power manage module. In the practical design, only the pre-conversion unit (up-conversion unit) is added with the multi-bands VCO 1100, the phase lock loop 1140 and the power manage module. Alternatively, the pose-conversion unit (down-conversion unit) is added with multi-bands VCO 1100, the phase lock loop 1140 and the power manage module. Certainly, there is no power manage module in the pre-conversion unit (up-conversion unit) and the power manage module is in the post-conversion unit (down-conversion unit). The embodiments in the previous description are included in the present invention, it is not limited herein.

Besides the power manage device is added in the operation of the adjusting of the tuner, in order to let the tuner of the present invention with better performance, there is a input resistance added in the low noise amplifier to automatically adjust the value of the input radio frequency. The detail description is in the following chapter.

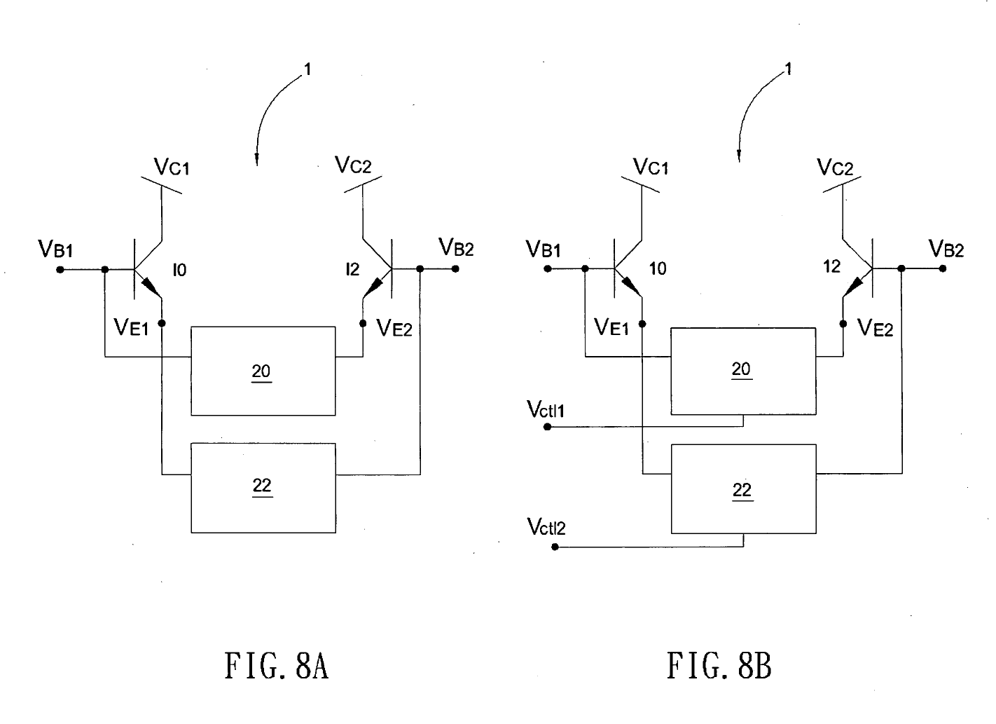

FIG. 8A is a view showing the low noise amplifier of the present invention. As shown in FIG. 8A, the low noise amplifier 1 includes a first active component 10, a second active component 12 and a plurality of adjustable attenuation device 20, 22. Each one of the active component in the low noise amplifier 1 includes a first end, a second end and a third end. In the present embodiment, the active components are BJT and the first end is a base end, the second end is the emitter end and the third end is a collector end. Besides, the adjustable attenuation devices 20, 22 are components with two ends, such as resistance, inductance, capacitance, diode and any combination above. The adjustable attenuation devices can be the component with three ends, such as BJT, FET, MOSFET or CMOS.

Please still referring to FIG. 8A, the base ends of the first active component 10 and the second active component 12 are connected to the input end and used to receive the broadband radio frequency fed from the antenna of the tuner. When the first adjustable attenuation device 20 is a two ends component, the first end is connected to the base end of the first active component 10 and the second end is connected to the emitter end of the second active component 12. Besides, the second adjustable attenuation device 22 is a two ends component too, the first end is connected to the base end of the first active component 10 and the second end is connected to the emitter end of the second active component 12. Obviously, the voltage (V_{B1}) of the base end of the first active component 10 and the voltage V_{E2} of the emitter end of the second active component 12 are adjusted or changed by changing the impedance of the adjustable attenuation device 22. Therefore, when the gains of the first active component and the second active component in the low noise amplifier of the present invention are adjusted, such as adjusting the gain o f the low noise amplifier by a power manage device, the input impedance of the low noise amplifier 1 is changeable in a small range, for example the input impedance is changeable within the 50±2Ω. Therefore, the tuner and the low noise amplifier can maintain in the optimum compatible impedance condition. Certainly, before the input signal is transmitted from the antenna of the tuner to the low noise amplifier 1, the input signal is optionally transmitted to amplifier circuit (not shown), such as an automatic gain controlled circuit.

Besides, in order to adjust the input impedance, the adjustable attenuation device 20 and 22 can be the adjustable component, such as adjustable resistance, adjustable inductance, adjustable capacitance and so on. The third end (such as collector end) of the first active component 10 and the second active component 12 is connected to the two ends component (not shown) to be the load of the low noise amplifier 1. The two ends component is resistance, inductance, capacitance, diode or any combinations above.

Now referring to FIG. 8B, FIG. 8B is a view showing another embodiment of the low noise amplifier in the present invention. The base ends of the first active component 10 and the second active component 12 are connected to the input end and used to receive the broadband radio frequency fed from the antenna of the tuner. When the first adjustable attenuation device 20 is a three ends component, such as a BJT, the third end (such as collector) is connected to the base end of the second active component 12 and the second end (such as emitter) is connected to the emitter of the first active component 10 and the first end (such as base) is connected to a voltage control end V_{ctl2} used to adjust voltage.

Obviously, the voltage (V_{B1}) of the base end of the first active component 10 and the voltage V_{E2} of the emitter end of the second active component 12 are adjusted or changed by adjusting the voltage of the voltage controlled end V_{ctl1} of the adjustable attenuation device 20 to change the impedance of the adjustable attenuation device 20. Similarly, the voltage (V_{B2}) of the base end of the second active component 12 and the voltage V_{E1} of the emitter end of the first active component 10 are adjusted or changed by adjusting the voltage of the voltage controlled end V_{ctl1} of the adjustable attenuation device 20 to change the impedance of the adjustable attenuation device 20. Therefore, when the gains of the first active component and the second active component in the low noise amplifier of the present invention are adjusted, such as adjusting the gain of the low noise amplifier by a power manage device, the input impedance of the low noise amplifier 1 is changeable in a small range, for example the input impedance is changeable within the 75±5Ω. Therefore, the tuner and the low noise amplifier can maintain in the optimum compatible impedance condition. Certainly, before the input signal is transmitted from the antenna of the tuner to the low noise amplifier 1, the input signal is optionally transmitted to amplifier circuit (not shown), such as a automatic gain controlled circuit.

Besides, in order to adjust the input impedance, the adjustable attenuation device 20 and 22 can be BJT, FET, MOSFET or CMOS. In the preferred embodiment, the voltage value of the voltage controlled end V_{ctl1}-V_{ctl2} can be chosen to be zero voltage. The third end (such as collector end) of the first active component 10 and the second active component 12 is connected to the two ends component (not shown) to be the load of the low noise amplifier 1. The two ends component is resistance, inductance, capacitance, diode or any combinations above.

Besides, the first adjustable attenuation device 20 and 22 shown in FIG. 8A and FIG. 8B of the present invention can be a plurality of components being parallel to each other. In other words, the first adjustable attenuation device 20 and the second adjustable attenuation device 22 can be formed by a plurality of adjustable attenuation devices being parallel connection.

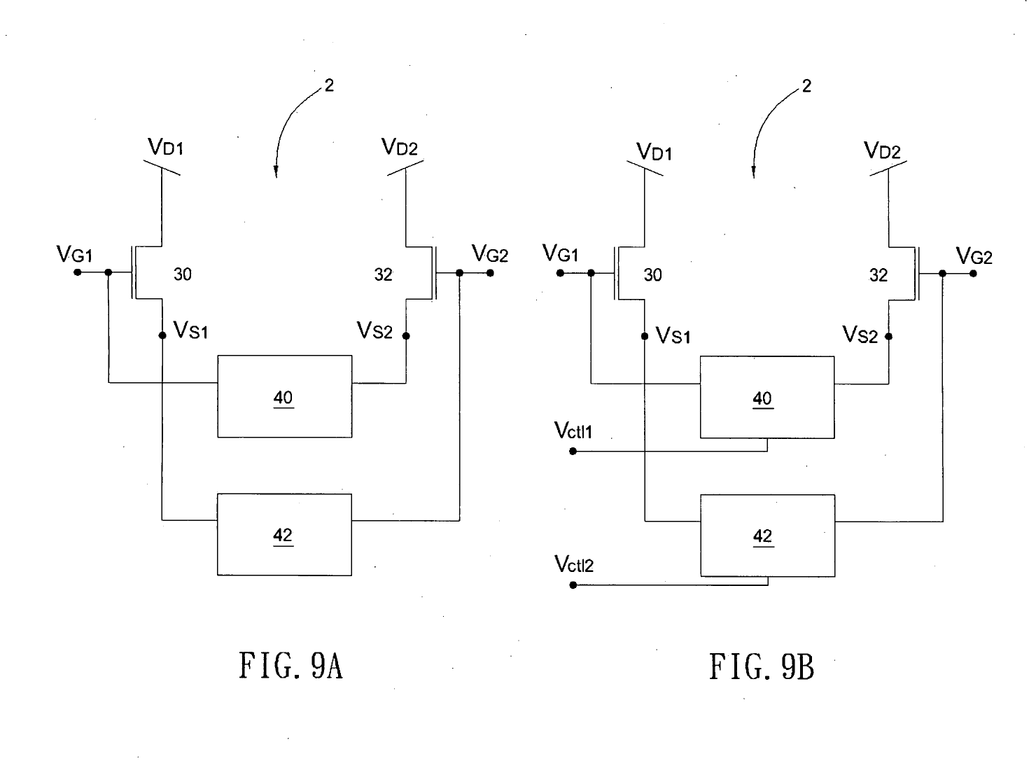

FIG. 9A is a view showing the low noise amplifier in another embodiment of the present invention. As shown in FIG. 9A, the low noise amplifier 2 includes a first active component 30, a second active component 32 and a plurality of adjustable attenuation device 40, 42. The active components 30 and 32 are FET, MOSFET, CMOS, and so on. The first end is a gate end, the second end is the source end and the third end is a drain end. Besides, the adjustable attenuation devices 40, 42 are components with two ends, such as resistance, inductance, capacitance, diode and any combination above. Besides, the adjustable attenuation devices 40, 42 are components with three ends, such as BJT, FET, MOSFET, CMOS and so on.

Obviously, the circuit structure in FIG. 9A is the same as the structure shown in FIG. 8A and FIG. 8B. The first active component is replaced from BJT to FET, MOSFET or CMOS. In the present embodiment, the NMOS is chosen to be the active component.

Please still referring to FIG. 9A, the gate ends of the first active component 30 and the second active component 32 are connected to the input end and used to receive the broadband radio frequency fed from the antenna of the tuner. When the first adjustable attenuation device 40 is a two ends component, the first end is connected to the gate end (V_{G1}) of the first active component 30 ant the second end is connected to the source end (V_{S2}) of the second active component 32.

Besides, as the second adjustable attenuation device 42 is a two ends component too, the first end is connected to the gate end (V_{G2}) of the second active component 32 and the second end is connected to the source end (V_{S2}) of the first active component 30. Obviously, when the gain of the low noise amplifier in the present invention is adjusted (such as a power manage module used to adjust the gain of the low noise amplifier), the input impedance of the low noise amplifier 2 can be adjusted within a small range, such as the impedance is within 50±2Ω, by the connection of the first adjustable attenuation device 40 and the second adjustable attenuation device 42.

Therefore, the tuner and the low noise amplifier can maintain in the optimum compatible impedance condition. Certainly, before the input signal is transmitted from the antenna of the tuner to the low noise amplifier 2, the input signal is optionally transmitted to amplifier circuit (not shown), such as a automatic gain controlled circuit.

Besides, in order to adjust the input impedance, the adjustable attenuation device 40 and 42 can be the adjustable component, such as adjustable resistance, adjustable inductance, and adjustable capacitance and so on. The third ends (such as drain ends) of the first active component 30 and the second active component 32 are connected to the two ends component (not shown) to be the load of the low noise amplifier 2. The two ends component is resistance, inductance, capacitance, diode or any combinations above.

Now referring to FIG. 9B, FIG. 9B is a view showing another embodiment of the low noise amplifier in the present invention. The gate ends of the first active component 30 and the second active component 32 in the low noise amplifier 2 are connected to the input end and used to receive the broadband radio frequency fed from the antenna of the tuner. When the first adjustable attenuation device 40 is a three ends component, such as a NMOS, the third end (such as drain end) is connected to the gate end (V_{G1}) of the first active component 30 and the second end (such as source end) is connected to the source end (V_{S2}) of the second active component 32 and the first end (such as gate end) is connected to a voltage control end Vctl1 used to adjust voltage. Besides, when the second adjustable attenuation device 42 is a three ends component (such as a NMOS), the third end (such as drain end) is connected to the gate end (V_{G2}) of the second active component 32 and the second end (such as source end) is connected to the source end (V_{S1}) of the first active component 30 and the first end (such as gate end) is connected to a voltage control end V_{ctl2} used to adjust voltage. Obviously, the voltage (V_{G1}) of the gate end of the first active component 30 and the voltage V_{S2} of the source end of the second active component 12 are adjusted or changed to be a fixed voltage value and the voltage of the voltage controlled end Vctl1 of the first adjustable attenuation device 40 is changed to a suitable voltage value, then the impedance of the adjustable attenuation device 20 is adjustable. Similarly, the voltage (V_{S1}) of the source end of the first active component 30 and the voltage (V_{G2}) of the gate end of the second active component 32 are adjusted or changed and the voltage of the voltage controlled end V_{ctl2} of the adjustable attenuation device 42 is adjusted, then the impedance of the adjustable attenuation device 42 is adjustable. Therefore, according to the connection of the adjustable attenuation device 40 or 42, the input impedance of the low noise amplifier 2 is changeable in a small range, for example the input impedance is changeable within the 75±5Ω. Therefore, the tuner and the low noise amplifier can maintain in the optimum compatible impedance condition. Certainly, before the input signal is transmitted from the antenna of the tuner to the low noise amplifier 2, the input signal is optionally transmitted to amplifier circuit (not shown), such as a automatic gain controlled circuit.

Besides, in order to adjust the input impedance, the adjustable attenuation device 40 and 42 can be BJT, FET, MOSFET or CMOS. In the preferred embodiment, the voltage value of the voltage controlled end V_{ctl1}-V_{ctl2} can be chosen to be zero voltage. The third ends (such as drain ends) of the first active component 30 and the second active component 32 are connected to the two ends component (not shown) to be the load of the low noise amplifier 2. The two ends component is resistance, inductance, capacitance, diode or any combinations above.

Besides, the first adjustable attenuation device 40 and 42 shown in FIG. 9A and FIG. 9B of the present invention can be a plurality of components being parallel to each other. In other words, the first adjustable attenuation device 40 and the second adjustable attenuation device 42 can be formed by a plurality of adjustable attenuation devices being parallel connection.

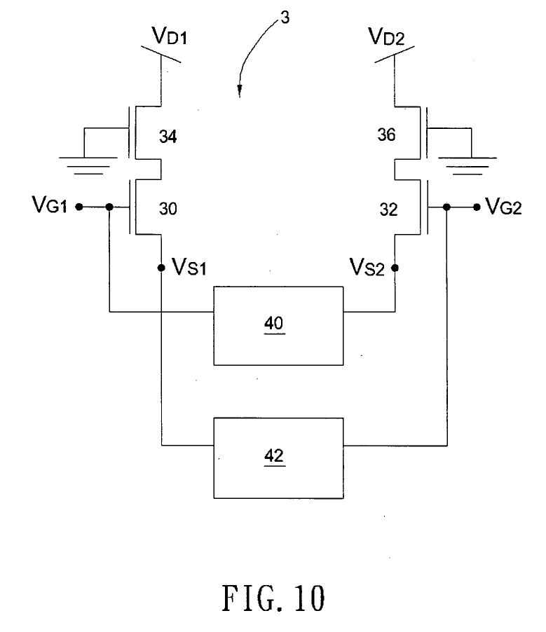

FIG. 10 is a view showing another embodiment of the low noise amplifier in the present invention. As shown in FIG. 10, the low noise amplifier 3 includes a first active component 30, a second active component 32, a third active component 34, a forth active component 36 and a plurality of adjust attenuation device 40 and 42. The adjustable attenuation devices can be BJT, FET, MOSFET or CMOS. The first end is a gate end, the second end is the source end and the third end is a drain end. Besides, the adjustable attenuation devices 40, 42 are components with two ends, such as resistance, inductance, capacitance, diode and any combination above. Besides, the adjustable attenuation devices 40, 42 are components with three ends, such as BJT, FET, MOSFET, CMOS and so on.

Obviously, the circuit structure of the embodiment shown in FIG. 10 is the same as the circuit shown in FIG. 9A and FIG. 9B. In FIG. 10, the active components 34 and 36 are respectively connected to the active components 30 and 32 shown in FIG. 9A and FIG. 9B. The third end (drain) of the active component 30 is connected to the second end (source) of the active component 34. Besides, the third end (drain) of the active component 34 is connected to a load device and the first end (gate) of the active component 34 is connected to the ground. The object to add an active component 34 and an active component 36 is to increase the output impedance of the low noise amplifier.

Obviously, the circuit structure in FIG. 10 is the same as the structure shown in FIG. 8A and FIG. 8B. The active component is a BJT, FET, MOSFET or CMOS. Because the circuit structure and the operated procedure are similar to the description above, the detail description is omitted herein.

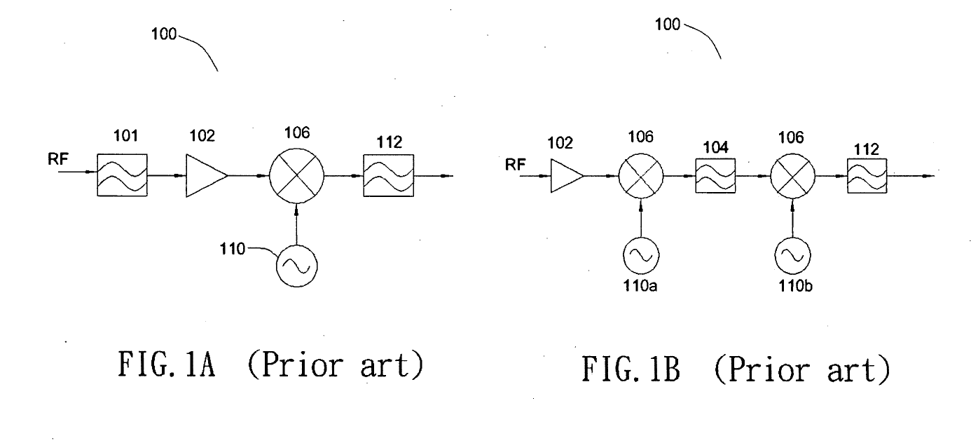

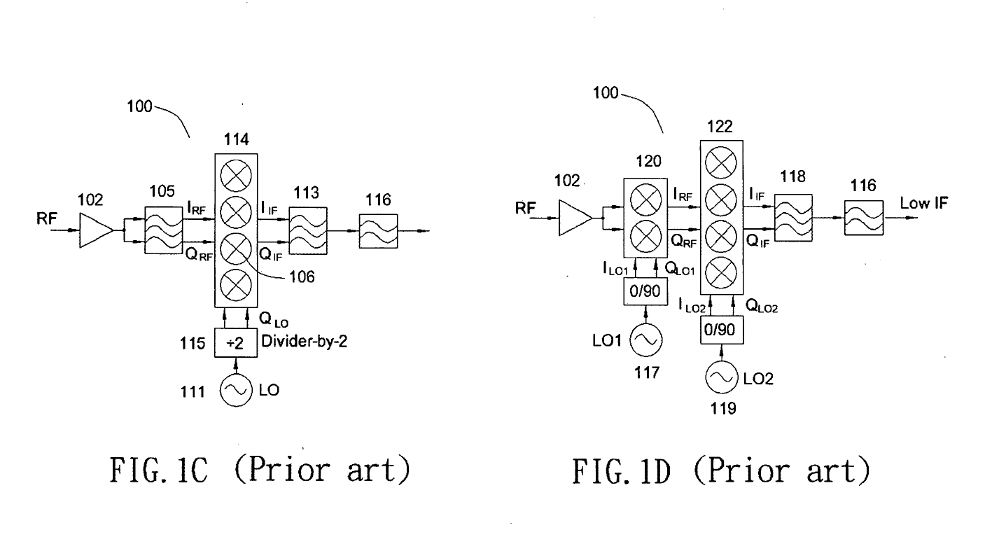

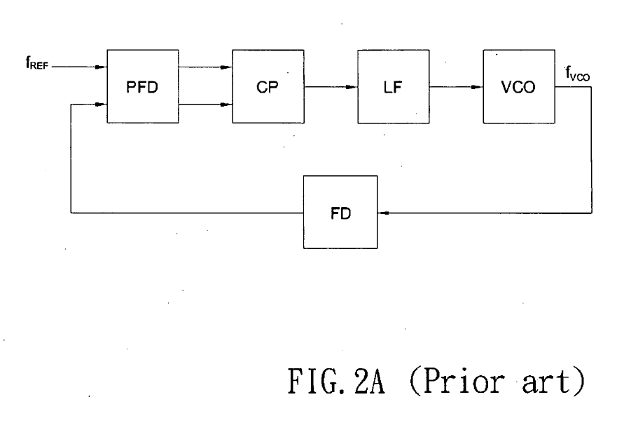

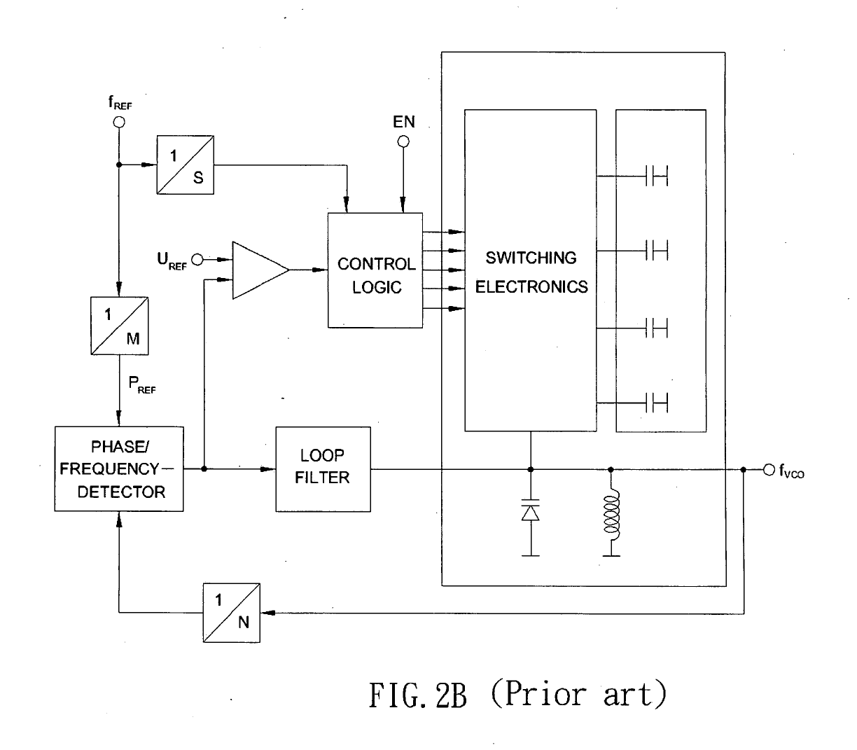

Besides, it should be noted that the low noise amplifier circuit described above can be formed on the wafer by the highly improved development of the semiconductor package technique. The tuner is able to be on die. The low noise amplifier of the present invention is able to replace the low noise amplifier 102 in the tuner 100 (as shown in FIG. 1A to FIG. 1D). By a suitable bias design, the tuner with the low noise amplifier of the present invention is in good impedance compatibility and the ability of the noise control in the circuit is increased.

What is claimed is:

1. A tunable multi-bands voltage-controlled oscillator (VCO), comprising:
a plurality of oscillators and each of the oscillators includes different oscillated range;
a plurality of capacitor tanks respectively disposed in each one of the oscillators and each one of the capacitors includes a plurality of parallel connective capacitors;
a voltage detector used to detect a voltage signal and choose one of the oscillators in accordance with the voltage signal;
a logic controller and one end of the logic controller is connected to the voltage detector and the other end of the logic controller is connected to the capacitor tanks and provides a controlled signal to drive the capacitors of the capacitor tanks; and
a multiplexer, and one end of the multiplexer is connected to the logic controller and the oscillators to output an oscillated frequency.

2. The tunable multi-bands VCO of claim 1, wherein each one of the capacitors in the capacitor tanks further includes a switch.

3. The tunable multi-bands VCO of claim 1, wherein the logic controller includes an accouter.

4. The tunable multi-bands VCO of claim 1, wherein the digital control signal includes an up-count or down-count control signal.

5. A frequency synthesizer having a phase/frequency detector, a power pump, a loop filter and a multi-bands VCO, and the multi-bands VCO is characterized in that:
a plurality of oscillators and each of the oscillators includes different oscillated range;
a plurality of capacitor tanks respectively disposed in each one of the oscillators and each one of the capacitors includes a plurality of parallel connective capacitors;
a voltage detector used to detect a voltage signal and choose one of the oscillators in accordance with the voltage signal;
a logic controller and one end of the logic controller is connected to the voltage detector and the other end of the logic controller is connected to the capacitor tanks and provides a controlled signal to drive the capacitors of the capacitor tanks; and
a multiplexer, and one end of the multiplexer is connected to the logic controller and the oscillators to output an oscillated frequency.

6. A frequency synthesizer including a multi-bands VCO and a mixer, and the multi-bands VCO is characterized in that:
a plurality of oscillators and each of the oscillators includes different oscillated range;
a plurality of capacitor tanks respectively disposed in each one of the oscillators and each one of the capacitors includes a plurality of parallel connective capacitors;
a voltage detector used to detect a voltage signal and choose one of the oscillators in accordance with the voltage signal;
a logic controller and one end of the logic controller is connected to the voltage detector and the other end of the logic controller is connected to the capacitor tanks and provides a controlled signal to drive the capacitors of the capacitor tanks; and
a multiplexer, and one end of the multiplexer is connected to the logic controller and the oscillators to output an oscillated frequency.

7. The frequency synthesizer of claim 6, wherein the multi-bands VCO further comprising a phase/frequency detector, a power pump and a loop filter.

8. A broadband tuner including a filter, a low noise amplifier, a mixer and a multi-bands VCO, and the multi-bands VCO is characterized in that:
a plurality of oscillators and each of the oscillators includes different oscillated range;
a plurality of capacitor tanks respectively disposed in each one of the oscillators and each one of the capacitors includes a plurality of parallel connective capacitors;
a voltage detector used to detect a voltage signal and choose one of the oscillators in accordance with the voltage signal;
a logic controller and one end of the logic controller is connected to the voltage detector and the other end of the logic controller is connected to the capacitor tanks and provides a controlled signal to drive the capacitors of the capacitor tanks; and
a multiplexer, and one end of the multiplexer is connected to the logic controller and the oscillators to output an oscillated frequency.

9. The broadband tuner of claim 8, wherein the multi-bands VCO further comprising a phase/frequency detector, a power pump and a loop filter.

10. The broadband tuner of claim 8, further comprising a power manage module, the power manage module comprises:
a power detector, wherein the first end of the power detector is connected to the input end of the broadband tuner and used to detect the power level of the input end and the second end is connected to the low noise amplifier; and
a power manage device, wherein the first end of the power manage device is connected to the third end of the power detector.

11. The broadband tuner of claim 10, wherein the power manage device is connected to the multi-bands VCO.

12. The broadband tuner of claim 10, wherein the power manage device is further connected to the low noise amplifier.

13. The broadband tuner of claim 10, further includes an automatic gain controlled circuit disposed between the power detector and the low noise amplifier.

14. The broadband tuner of claim 8, wherein the low noise amplifier comprises:
a first active component including a first end, a second end and a third end, wherein the first end is connected to the input end of the single frequency conversion device;
a second active component including a first end, a second end and a third end, wherein the first end is connected to the another input end of the single frequency conversion device;
a first attenuation device including a first end and a second end, wherein the first end is connected to the first end of the first active component and the second end is connected to the second end of the second active component; and
a second attenuation device including a first end and a second end, wherein the first end is connected to the second end of the first active component and the first end is connected to the second end of the second active component.

15. The broadband tuner of claim 8, wherein the oscillator in the multi-bands VCO is an orthotropic oscillator.

16. A broadband tuner made by serial connective of a first single frequency conversion device and a second single frequency conversion device, wherein the first single frequency conversion device includes a filter, a low noise amplifier, a mixer and a multi-bands VCO, and the second single frequency conversion device includes a filter, a low noise amplifier, a mixer and a multi-bands VCO, are characterized in that:
the multi-bands VCO comprises:
a plurality of oscillators and each of the oscillators includes different oscillated range;
a plurality of capacitor tanks respectively disposed in each one of the oscillators and each one of the capacitors includes a plurality of parallel connective capacitors;
a voltage detector used to detect a voltage signal and choose one of the oscillators in accordance with the voltage signal;
a logic controller and one end of the logic controller is connected to the voltage detector and the other end of the logic controller is connected to the capacitor tanks and provides a controlled signal to drive the capacitors of the capacitor tanks; and
a multiplexer, and one end of the multiplexer is connected to the logic controller and the oscillators to output an oscillated frequency.

17. The broadband tuner of claim 16, wherein the multi-bands VCO further comprises a phase/frequency detector, a power pump and a loop filter.

18. The broadband tuner of claim 16, wherein the first single frequency conversion device and the second single frequency conversion device further comprise a power manage module, the power manage module comprises:
a power detector, wherein the first end of the power detector is connected to the input end of the broadband tuner and used to detect the power level of the input end and the second end is connected to the low noise amplifier; and
a power manage device, wherein the first end of the power manage device is connected to the third end of the power detector.

19. The broadband tuner of claim 16, wherein the low noise amplifier comprises:
a first active component having a first end, a second end and a third end, wherein the first end is connected to the input end of the single frequency conversion device;
a second active component having a first end, a second end and a third end, wherein the first end is connected to the another input end of the single frequency conversion device;
a first attenuation device having a first end and a second end, wherein the first end is connected to the first end of the first active component and the second end is connected to the second end of the second active component; and
a second attenuation device having a first end and a second end, wherein the first end is connected to the second end of the first active component and the first end is connected to the second end of the second active component.

20. An adjusting output frequency of a multi-bands VCO, comprising:
providing a plurality of oscillators and each of the oscillators includes different oscillated range;
providing a plurality of capacitor tanks respectively disposed in each one of the oscillators and each one of the capacitors includes a plurality of parallel connective capacitors;
providing a voltage detector used to detect a voltage signal and choose one of the oscillators in accordance with the voltage signal;
providing a logic controller and one end of the logic controller is connected to the voltage detector and the other end of the logic controller is connected to the capacitor tanks and provides a controlled signal to drive the capacitors of the capacitor tanks; and
providing a multiplexer, and one end of the multiplexer is connected to the logic controller and the oscillators to output an oscillated frequency.
